(19) United States
(12) Patent Application Publication
(10) Pub. No.: US 2010/0260931 A1
(43) Pub. Date: Oct. 14, 2010

(54) METHOD AND APPARATUS FOR USING A VERTICAL FURNACE TO INFUSE CARBON NANOTUBES TO FIBER

(75) Inventors: Harry C. MALECKI, Abingdon, MD (US); Tushar K. Shah, Columbia, MD (US); Mark R. Alberding, Glen Arm, MD (US)

Correspondence Address: MCDERMOTT WILL & EMERY LLP, 18191 VON KARMAN AVE., SUITE 500, IRVINE, CA, 92612-7108, US

(73) Assignee: Lockheed Martin Corporation, Bethesda, MD (US)

(21) Appl. No.: 12/757,907

(22) Filed: Apr. 9, 2010

Related U.S. Application Data
(60) Provisional application No. 61/168,526, filed on Apr. 10, 2009.

(51) Int. Cl. B05D 1/00; C23C 16/00

(52) U.S. Cl. 427/180; 118/724; 977/742; 977/843

(57) ABSTRACT

A method for forming a CNT infused substrate comprises exposing a catalyst nanoparticle, a carbon feedstock gas, and a carrier gas to a CNT synthesis temperature, allowing a CNT to form on the catalyst nanoparticle, cooling the CNT, and exposing the cooled CNT to a surface of a substrate to form a CNT infused substrate.

### STATEMENT OF RELATED APPLICATIONS

This application claims priority to U.S. Provisional Application No. 61/168,526, filed on Apr. 10, 2009, which is incorporated herein by reference in its entirety.

### STATEMENT REGARDING FEDERALLY SPONSORED RESEARCH OR DEVELOPMENT

Not applicable.

### FIELD OF THE INVENTION

The present invention relates in general to a system, method and apparatus for the continuous synthesis of carbon nanotubes.

### BACKGROUND OF THE INVENTION

Fibers are used for many different applications in a wide variety of industries, such as the commercial aviation, recreation, industrial and transportation industries. Carbon nanotubes (“CNTs”) exhibit impressive physical properties such as exhibiting roughly eighty times the strength, six times the stiffness (i.e., Young's Modulus), and one-sixth the density of high carbon steel. CNTs can be useful when integrated into certain fibrous materials such as composite materials. Hence, developing CNTs within composite materials having these desirable properties is of significant interest.

A composite material is a heterogeneous combination of two or more constituents that differ in form or composition on a macroscopic scale. Two constituents of a composite include a reinforcing agent and a resin matrix. In a fiber-based composite, the fibers act as a reinforcing agent. The resin matrix keeps the fibers in a desired location and orientation and also serves as a load-transfer medium between fibers within the composite. Due to their exceptional mechanical properties, CNTs are used to further reinforce the fiber in composite materials.

To realize the benefit of fiber properties with a composite, a good interface between the fibers and the matrix is needed. This can be achieved through the use of a surface coating, typically referred to as “sizing.” The sizing provides a physicochemical link between the fiber and the resin matrix and has a significant impact on the mechanical and chemical properties of the composite. The sizing can be applied to fibers during their manufacture. Generally, conventional CNT synthesis has required high temperatures in the range of 700° C. to 1500° C. However, many fibers and sizings on which CNTs are to be formed are adversely affected by the high temperatures generally required for CNT synthesis in conventional processes. For example, at such relatively higher temperatures, the mechanical properties of a glass fiber, such as “E-glass,” degrade significantly. Using in-situ continuous carbon-nanotube growth processes, E-glass fibers can experience losses in strength of up to about 50%. These losses can propagate and cause further problems down the process line as deteriorated fibers can fray and break under tension and in low-radius turns. Other fibers including carbon fibers can experience similar problems. Alternative methods and systems for providing low temperature in-line CNT synthesis are desired.

### SUMMARY OF THE INVENTION

In some embodiments, a method for forming a CNT infused substrate comprises exposing a catalyst nanoparticle, a carbon feedstock gas, and a carrier gas to a CNT synthesis temperature, allowing a CNT to form on the catalyst nanoparticle, cooling the CNT, and exposing the cooled CNT to a surface of a substrate to form a CNT infused substrate. In some embodiments, the substrate can be functionalized prior to exposing the substrate to the CNT. The CNT infused substrate can also be functionalized. In some embodiments, the method also comprises providing a catalyst solution comprising a catalyst and a solvent, and atomizing the catalyst solution and allowing the solvent to evaporate leaving the catalyst nanoparticle.

In some embodiments, a system comprises a carrier gas source that provides a carrier gas; a catalyst source that provides a catalyst nanoparticle; a carbon feedstock source that provides a carbon feedstock; a substrate source that provides a substrate; and a CNT growth reactor comprising an inlet device that receives the carrier gas, the catalyst nanoparticle, and the carbon feedstock and introduces the carrier gas, the catalyst nanoparticle, and the carbon feedstock into a CNT growth zone; a heating element that heats the carrier gas, the catalyst nanoparticle, and the carbon feedstock to a CNT synthesis temperature within the CNT growth zone to allow a CNT to synthesize on the catalyst and form a synthesized CNT; a dispersion hood that receives the synthesized CNT and cools the synthesized CNT; and a CNT infusion chamber that receives the synthesized CNT and the substrate and exposes the substrate to the cooled synthesized CNT to produce a CNT infused substrate. In some embodiments, the substrate is functionalized.

In some embodiments, a method comprises providing a catalyst nanoparticle, a carbon feedstock gas, and a carrier gas; heating the catalyst nanoparticle, the carbon feedstock gas, and the carrier gas to a CNT synthesis temperature; allowing a CNT to form on the catalyst nanoparticle; cooling the CNT; providing a substrate; exposing the substrate to the cooled CNT to form a CNT infused substrate; and forming a composite material, wherein the composite material comprises the CNT infused substrate. In some embodiments, the substrate is functionalized, and in some embodiments, the CNT infused substrate is functionalized prior to forming a composite material. In some embodiments, the substrate is provided on a dynamic basis.

### BRIEF DESCRIPTION OF THE DRAWINGS

FIG. 1 depicts a reactor configuration for the production of carbon nanotubes in accordance with some embodiments of the invention.

FIG. 2 depicts a method for providing a CNT infused substrate suitable for use in a composite material according to some embodiments of the invention.

FIG. 3 depicts a E-Glass fiber with CNTs infused on its surface via a vertical furnace growth chamber in accordance with some embodiments of the invention.

### DETAILED DESCRIPTION

The present invention relates in general to a system, method and apparatus for the continuous synthesis of CNTs and infusion on a substrate. In particular, the invention provides at least some separation between the high-temperature synthesis of carbon nanotubes and their application to a substrate. CNTs can be advantageously synthesized in a high temperature reactor and subsequently infused on a variety of substrates to produce carbon nanotube-infused (“CNT-infused”) substrates. The process is particularly advantageous for use with temperature sensitive substrates or substrates with temperature sensitive sizings. The disposition of CNTs on a substrate can serve many functions including, for example, as a sizing agent to protect against damage from moisture, oxidation, abrasion, and compression. A CNT-based sizing can also serve as an interface between the substrate and a matrix material in a composite. The CNTs can also serve as one of several sizing agents coating the substrate. Moreover, CNTs infused on a substrate can alter various properties of the substrate, such as thermal and/or electrical conductivity, and/or tensile strength, for example. The processes employed to make CNT-infused substrates can provide CNTs with substantially uniform length and distribution to impart their useful properties uniformly over the substrate that is being modified. Furthermore, the processes disclosed herein can generate CNT-infused substrates of spoolable dimensions.

The system and method disclosed herein also make it possible to use various sizing and substrates such as polyaramid fibers including Kevlar, which cannot withstand high operating temperatures utilized in some conventional carbon nanotube synthesis processes. In addition, the system and the method of this invention can allow a temperature sensitive substrate to be used for the formation of a composite material infused with CNTs due at least in part to the relatively low temperature at which the CNTs contact and are infused onto the substrate. A further advantage of the present system and method is that continuous synthesis of CNTs can be obtained, facilitating mass production of composite materials with CNTs. The continuous synthesis process can be carried out on a dynamic substrate, e.g., a substrate entering a reactor through an inlet, traversing through the reactor and exiting from an outlet of the reactor.

The processes described herein can allow for the continuous production of CNTs of uniform length and distribution along spoolable lengths of tow, tapes, fabrics and other 3D woven structures. While various mats, woven and non-woven fabrics and the like can be functionalized by processes of the invention, it is also possible to generate such higher ordered structures from the parent tow, yarn or the like after CNT functionalization of these parent materials. For example, a CNT-infused woven fabric can be generated from a CNT-infused fiber tow.

The term “substrate” is intended to include any material upon which CNTs can be synthesized and can include, but is not limited to, a carbon fiber, a graphite fiber, a cellulosic fiber, a glass fiber, a metal fiber (e.g., steel, aluminum, etc.), a ceramic fiber, a metallic-ceramic fiber, cellulosic fiber, an aramid fiber (e.g., Kevlar), thermoplastics, or any substrate comprising a combination thereof. The substrate can include fibers or filaments arranged, for example, in a fiber tow (typically having about 1000 to about 12000 fibers) as well as planar substrates such as fabrics, tapes, ribbons, graphene sheets, silicon wafers, or other fiber broadgoods, and materials upon which CNTs can be synthesized.

As used herein the term “spoolable dimensions” refers to substrates having at least one dimension that is not limited in length, allowing for the material to be stored on a spool or mandrel. Substrates of “spoolable dimensions” have at least one dimension that indicates the use of either batch or continuous processing for CNT infusion as described herein. One substrate of spoolable dimensions that is commercially available is exemplified by G34-700 12 k carbon fiber tow with a tex value of 800 (1 tex=1 g/1,000 m) or 620 yard/lb (available from Grafil, Inc., Sacramento, Calif.). Commercial carbon fiber tow, in particular, can be obtained in 5, 10, 20, 50, and 100 lb. (for spools having high weight, usually a 3 k/12K tow) spools, for example, although larger spools may require special order.

As used herein, the term “carbon nanotube” (CNT, plural CNTs) refers to any of a number of cylindrically-shaped allotropes of carbon of the fullerene family including graphene, vapor grown carbon fibers, carbon nanofibers, single-walled CNTs (SWNTs), double-walled CNTs (DWNTs), and multi-walled CNTs (MWNTs). CNTs can be capped by a fullerene-like structure or open-ended. CNTs include those that encapsulate other materials.

As used herein “uniform in length” refers to length of CNTs grown in a reactor. “Uniform length” means that the CNTs have lengths with tolerances of plus or minus about 20% of the total CNT length or less, for CNT lengths varying from between about 1 micron to about 500 microns. At very short lengths, such as 1-4 microns, this error can be in a range from between about plus or minus 20% of the total CNT length up to about plus or minus 1 micron, that is, somewhat more than about 20% of the total CNT length.

As used herein “uniform in distribution” refers to the consistency of density of CNTs on a substrate. “Uniform distribution” means that the CNTs have a density on the substrate with tolerances of plus or minus about 10% coverage defined as the percentage of the surface area of the substrate covered by CNTs. This is equivalent to ±1500 CNTs/μm² for an 8 nm diameter CNT with 5 walls. Such a value assumes the space inside the CNTs as fillable.

As used herein, the term “infused” means bonded and “infusion” means the process of bonding. Such bonding can involve direct covalent bonding, ionic bonding, pi-pi, and/or Van der Waals force-mediated physisorption. In some embodiments, the CNTs can be directly bonded (e.g., covalently or through a pi-pi bond) to the substrate, for example, at a point at which the substrate has been functionalized. Bonding can be indirect, such as the CNT infusion to the substrate via a coating disposed between the CNTs and substrate. In some embodiments, the CNTs can be indirectly bonded (e.g., through physisorption) to the substrate without any intervening materials and/or functionalization. In the CNT-infused substrates disclosed herein, the CNTs can be “infused” to the substrate directly or indirectly. The particular manner in which a CNT is “infused” to a substrates can be referred to as a “bonding motif.”

As used herein, the term “transition metal” refers to any element or alloy of elements in the d-block of the periodic table. The tetin “transition metal” also includes salt forms of the base transition metal element such as oxides, carbides, chlorides, chlorates, acetates, sulfides, sulfates, nitrides, nitrates and the like.

As used herein, the term “nanoparticle” or NP (plural NPs), or grammatical equivalents thereof refers to particles sized between about 0.1 to about 100 nanometers in equivalent spherical diameter, although the NPs need not be spherical in shape. Transition metal NPs, in particular, serve as catalysts for CNT synthesis within the reactor.

As used herein, the term “carbon feedstock” refers to any carbon compound gas, solid, or liquid that can be volatilized, nebulized, atomized, or otherwise fluidized and is capable of dissociating or cracking at high temperatures into at least some free carbon radicals and which, in the presence of a catalyst, can form CNTs.

As used herein, the term “free carbon radicals” refers to any reactive carbon species capable of adding to the growth of a CNT. Without intending to be limited by theory, it is believed that a free carbon radical adds to the growth of a CNT by associating with a CNT catalyst to form a CNT or increase the length of an existing CNT.

As used herein, the term “sizing agent,” “fiber sizing agent,” or just “sizing,” refers collectively to materials used in the manufacture of some substrates (e.g., carbon fibers) as a coating to protect the integrity of substrate, provide enhanced interfacial interactions between a substrate and a matrix material in a composite, and/or alter and/or enhance particular physical properties of a substrate. In some embodiments, CNTs infused to substrates can behave as a sizing agent.

As used herein, the term “material residence time” refers to the amount of time a discrete point along a substrate of spoolable dimensions is exposed to synthesized CNTs within the reactor during the CNT infusion processes described herein. This definition includes the residence time when employing multiple CNT growth chambers.

As used herein, the term “linespeed” refers to the speed at which a substrate of spoolable dimensions can be fed through the CNT infusion processes described herein, where linespeed is a velocity determined by dividing CNT chamber(s) length by the material residence time.

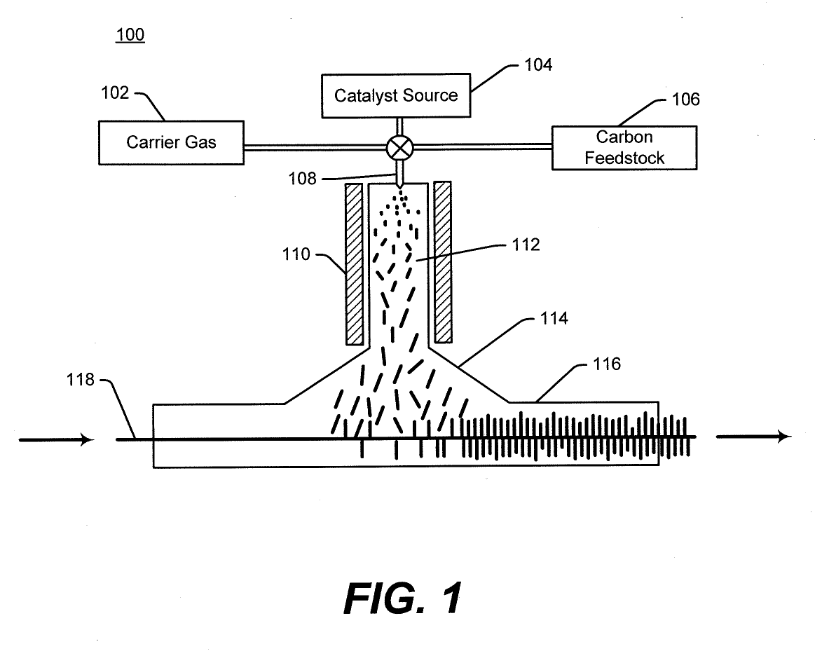

Referring to FIG. 1, there is illustrated a schematic diagram of a reactor 100 for synthesis of a CNT infused substrate. As depicted in FIG. 1, catalyst source 104, carbon feedstock source 106, and carrier gas source 102 are introduced at the top of the CNT growth zone 112 through an inlet device 108. A heating element 110 can be used to raise the temperature of the mixture to promote the formation of CNTs. As the CNTs grow, they can pass through a dispersion hood 114 to cool prior to entering the infusion chamber 116 containing the substrate 118, which in some embodiments, can be functionalized. The synthesized CNTs can infuse to substrate 118 to produce a CNT infused substrate before passing out of the reactor 100 for further processing.

In some embodiments, catalyst source 104 provides a catalyst for initiating the synthesis of CNTs. Such a catalyst can take the form of nano-sized particles of a catalyst. The catalyst employed can be a transition metal nanoparticle which can be any d-block transition metal as described above. In addition, the nanoparticles (NPs) can include alloys and non-alloy mixtures of d-block metals in elemental form or in salt form, and any mixtures thereof. Such salt forms include, without limitation, oxides, carbides, chlorides, chlorates, acetates, sulfides, sulfates, nitrides, nitrates and mixtures thereof. Non-limiting exemplary transition metal NPs include Ni, Fe, Co, Mo, Cu, Pt, Au, and Ag and salts thereof. Many of these transition metal catalysts are commercially available from a variety of suppliers, including, for example, Ferrotec Corporation (Bedford, N.H.).

In some embodiments, the catalyst can be in a colloidal solution or a metal salt solution. Other catalyst solutions can also be used. In some embodiments, commercial dispersions of CNT-forming transition metal nanoparticle catalyst are available and are used without dilution. In other embodiments, commercial dispersions of catalyst can be diluted. Whether to dilute such solutions can depend on the conditions within the reactor and the relative flow rates of the catalyst, the carrier gas, and the carbon feedstock. Catalyst solutions can comprise a solvent that allows the catalyst to be uniformly dispersed throughout the catalyst solution. Such solvents can include, without limitation, water, acetone, hexane, isopropyl alcohol, toluene, ethanol, methanol, tetrahydrofuran (THF), cyclohexane or any other solvent with controlled polarity to create an appropriate dispersion of the CNT-forming catalyst nanoparticles or salt solutions. Concentrations of CNT-forming catalyst can be in a range from about 1:1 to about 1:10000 of catalyst to solvent in the catalyst solution.

Again referring to FIG. 1, carbon feedstock source 106 is in fluid communication with the top of the CNT growth zone 112 through an inlet device 108. In another embodiment, gases from carbon feedstock source 106 and carrier gas source 102 are mixed before the gas mixture is supplied to the CNT growth zone 112 through an inlet device 108.

The carbon feedstock can be any carbon compound gas, solid, or liquid that can be volatilized, nebulized, atomized, or otherwise fluidized and is capable of dissociating or cracking at high temperatures into at least some free carbon radicals. The free carbon radicals can then form CNTs in the presence of a catalyst. In some embodiments, the carbon feedstock can comprise acetylene, ethylene, methanol, methane, propane, benzene, natural gas, or any combination thereof. In some exemplary embodiments, when a carbon feedstock comprising acetylene is heated to a temperature between about 450° C. and about 1000° C. and fed into CNT growth zone 112, at least a portion of the acetylene dissociates into carbon and hydrogen in the presence of a catalyst nanoparticle. The temperature of the CNT growth zone facilitates rapid dissociation of acetylene but could adversely impact the physical and chemical properties of the substrate and/or any sizing materials present. By separating the CNT growth zone 112 from the substrate the integrity of the substrate and any sizing materials or other coatings can be preserved during CNT formation and subsequent infusion on the substrate.

The use of a carbon feedstock such as acetylene can reduce the need for a separate process of introducing hydrogen into CNT growth zone 112, which can be used to reduce a catalyst containing an oxide. The dissociation of a carbon feedstock may provide hydrogen, which can reduce the catalyst particles to pure particles (e.g., in a pure elemental form) or at least to an acceptable oxide level. Without being bound by theory, it is believed that the stability of an oxide used as a catalyst can affect the reactivity of the catalyst particles. As the stability of the oxide increases, the catalyst particles generally become less reactive. Reduction (e.g., through contact with hydrogen) to a more unstable oxide or a pure metal can increase the reactivity of the catalyst. For example, if the catalyst comprises iron oxide (e.g., magnetite), such an iron oxide particle is not conducive to the synthesis of CNTs due to the stability of the iron oxide. Reduction to a less stable oxidation state or pure iron can increase the reactivity of the catalyst particle. The hydrogen from acetylene can remove the oxide from the catalyst particles or reduce the oxide to a less stable oxide form.

A carrier gas can be used to control the bulk flow of catalyst and carbon feedstock through the CNT growth zone 112 in addition to removing oxygen, which can be detrimental to the growth of CNTs from CNT growth zone 112. If oxygen is present in CNT growth zone 112, the carbon radicals formed from the carbon feedstock tend to react with the oxygen to form carbon dioxide and/or carbon monoxide, instead of forming CNTs using the catalyst nanoparticles as seed structures. In addition, the formation of a CNT in the presence of oxygen can result in the oxidative decomposition of the CNT. The carrier gas can comprise any inert gas that does not detrimentally impact the CNT growth process. In some embodiments, the carrier gas can include, but is not limited to, nitrogen, helium, argon, or any combination thereof. In some embodiments, the carrier gas can comprise a gas that allows for control of the process parameters. Such a gas can include, but is not limited to, water vapor and/or hydrogen. In some embodiments, the carbon feedstock can be provided in a range between about 0% to about 15% of the total gas mixture.

As shown in FIG. 1, the catalyst from catalyst source 104, the gases from carbon feedstock source 106, and the gases from carrier gas source 102 can be supplied to the CNT growth zone 112 through an inlet device 108. The inlet device can comprise one or more devices for introducing the gases and the catalyst together or separately. In some embodiments, inlet device 108 comprises an atomizer and the catalyst is introduced to the reactor as a catalyst solution in an atomized form. This can be achieved via a nebulizer, atomization nozzle, or other techniques. Industrial atomizer or misting nozzle designs can be based on the use of high pressure fluid (e.g., a liquid) or a gas assist nozzle design. In high-pressure liquid nozzles, the catalyst solution pressure can be used to accelerate the fluid through small orifices and create shear forces inside nozzle passages that break down the catalyst solution into micron size droplets. The shear energy is supplied by the catalyst solution, which can be at high-pressure. In the case of gas assist atomizer nozzles, the inertial force created by supersonic gas jets (e.g., the carbon feedstock, carrier gas, or a combination of the two) shears the catalyst solution while inside the atomizer nozzle and upon exiting the atomizer nozzle, breaks the catalyst solution into micron size droplets.

In some embodiments, the catalyst solution is passed through a nebulizer to produce the catalyst solution in an atomized form. A nebulizer may operate through the introduction of a high pressure gas (e.g., the carbon feedstock, the carrier gas, or a combination of the two) through a reservoir containing the catalyst solution. The action of the gas passing through the solution can entrain a portion of the catalyst solution to produce an atomized carrier solution. Alternatively, a membrane oscillating at a high frequency and in contact with the carrier solution can be used to produce an atomized catalyst solution. A gas can then pass over the atomized catalyst solution to carry the atomized catalyst solution through inlet device 108 into the CNT growth zone 112.

In some embodiments in which a gas is used in conjunction with inlet device 108 to produce an atomized catalyst solution, the gas can comprise the carrier gas, the carbon feedstock, or any mixture thereof. In some embodiments, a high-pressure liquid nozzle is used to atomize the catalyst solution and the carrier gas and the carbon feedstock are introduced through inlet device 108 separate from the catalyst solution, either individually or as a combined gas mixture. As the catalyst solution passes through inlet device 108, the catalyst solution can vaporize and leave a catalyst nanoparticle. This can occur as a result of the catalyst being in a colloidal solution so that the fluid portion of the solution vaporizes leaving a catalyst nanoparticle, or the catalyst can be a salt dissolved in a solvent so that the evaporation of the solvent results in the crystallization of a catalyst nanoparticle.

As shown in FIG. 1, heating element 110 can be used to raise the temperature of the components entering the CNT growth zone 112 to promote the formation of CNTs. In some embodiments, the heating element can comprise any type of heating element capable of raising the temperature of the CNT growth zone, the catalyst nanoparticles, the carbon feedstock, or any combination thereof to the appropriate reaction temperature. In some embodiments, heating element 110 can comprise a plurality of individual heating elements capable of producing a desired temperature and/or a desired temperature profile within the CNT growth zone. In some embodiments, heating element 110 can include, but is not limited to, infrared or resistive heaters disposed adjacent to or within the growth zone. Heating element 110 heats the catalyst and gases to a CNT synthesis temperature, which is typically in the range of about 450° C. to about 1000° C. At these temperatures, at least a portion of the carbon feedstock can dissociate or crack into at least some free carbon radicals. The catalyst nanoparticles can then react with the free carbon radicals to synthesize CNTs. In some embodiments, hydrogen is also produced by the dissociation of the carbon feedstock, which can then reduce the catalyst to a pure metal particle.

As the carbon feedstock, the carrier gas, and the catalyst particles are heated in the CNT growth zone 112, CNTs synthesize on the catalyst particles as they pass through the CNT growth zone 112. The synthesized CNTs can comprise agglomerates of synthesized CNTs and one or more catalyst particles. The length of the CNTs is affected by several factors including, but not limited to, the carbon feedstock concentration, the temperature, the catalyst composition, the carrier gas flowrate, and the residence time of the catalyst particles and synthesizing CNTs in the CNT growth zone, which may be a function of the length of the CNT growth zone and the gas flow characteristics (e.g., velocity, etc.).

In some embodiments, some or all of the parts of heating element 110 and/or CNT growth zone 112 can be constructed of metal, (e.g., stainless steel, a high nickel steel alloy, etc.). This use of metal, and stainless steel in particular, can lead to carbon deposition (i.e., soot and by-product formation). Once carbon deposits to a monolayer on the walls of the device, carbon will readily deposit over itself. In some embodiments, the metal can be coated to prevent or reduce carbon deposits. Suitable coating can include, but are not limited to, silica, alumina, magnesium oxide, and any combination thereof. When carbon deposits occur, periodic cleaning and maintenance can be employed to prevent any carbon deposition from obstructing the flow of the gases, the catalyst particles, the CNTs, or any combination thereof.

As shown in FIG. 1, the CNTs pass to a dispersion hood 114 after passing out of the CNT growth zone 112 where the synthesized CNTs can cool prior to entering the infusion chamber 116 containing a substrate 118. The dispersion hood 114 can provide a buffer region where the gas mixture (e.g., any remaining carbon feedstock gas, dissociation products, and/or carrier gas) and synthesized CNTs can be cooled before reaching the substrate. In some embodiments, the dispersion hood can comprise one or more cooling devices such as a heat transfer arrangement for cooling the outside of the dispersion hood or otherwise removing heat from the gas mixture containing the synthesized CNTs. In some embodiments, the dispersion hood is designed so that the temperature of the synthesized CNTs is lowered to a temperature ranging from about 25° C. to about 450° C. By virtue of the reactor design, the substrate is not exposed to the high temperatures that are required for CNT synthesis. As a consequence, in embodiments utilizing temperature sensitive substrates, the degradation of the substrate and/or removal of the sizing that would otherwise compromise the substrate properties can be avoided.

As shown in FIG. 1, the synthesized CNTs can infuse to substrate 118 to produce a CNT infused substrate before passing out of the reactor 100 for further processing. The substrate can include any of those materials listed above as being suitable for use as a substrate. In some embodiments, the substrate can comprise E-glass fibers coated with a sizing material. In other embodiments, the substrate can include other fibers, such as inexpensive glass fibers and carbon fibers. In still other embodiments, the substrate can be an aramid fiber such as Kevlar. Fibers can be supplied in bundles, known as “tows.” A tow can have between about 1000 to about 12000 fiber filaments. In some embodiments, a fiber filament can have a diameter of about 10 microns, although fiber filaments having other diameters can be used. Fibers can also include a carbon yarn, a carbon tape, a unidirectional carbon tape, a carbon fiber-braid, a woven carbon fabric, a non-woven carbon fiber mat, a carbon fiber ply, a 3D woven structure and the like.

In some embodiments, the substrate can be coated with a sizing. Sizing can vary widely in type and function and can include, but is not limited to, surfactants, anti-static agents, lubricants, siloxanes, alkoxysilanes, aminosilanes, silanes, silanols, polyvinyl alcohol, starch, and mixtures thereof. Such sizing can be used to protect the CNTs themselves or provide further properties to the fiber not imparted by the presence of the infused CNTs. In some embodiments, any sizing can be removed prior to the substrate entering reactor 100. In some embodiments, a coating such as silica, alumina, magnesium oxide, silane, siloxane, or other type coating can be coated on the substrate to aid in bonding the CNTs to the substrate. Without intending to be limited by theory, it is believed that the bonding of the CNTs to the substrate with this type of coating is more mechanical and depends on physisorption and/or mechanical interlocking.

In some embodiments, the substrate can be functionalized to promote the infusion of the synthesized CNTs to the substrate. Functionalization generally involves the creation of polar functional groups on the surface of the substrate. Suitable functional groups can include, but are not limited to, amine groups, carbonyl groups, carboxyl groups, fluorine-based groups, silane groups, siloxane groups, and any combination thereof. The polar groups can take place in the infusion of the synthesized CNTs to the substrate through the interaction of the polar group and the carbon atoms in the CNTs. The substrate can be functionalized using any technique known to one of ordinary skill in the art. Suitable techniques can include, but are not limited to, sputtering, plasma functionalization, and passing the substrate through one or more suitable chemical solutions.

As shown in FIG. 1, the CNTs can infuse to substrate 118 to produce a CNT infused substrate before passing out of the reactor 100 for further processing. As indicated by the arrows in FIG. 1, substrate 118 can be supplied to reactor on a dynamic basis. Without intending to be limited by theory, it is believed that the synthesized CNTs can comprise one or more carbon radicals (e.g., dangling carbons) due to disorder along the CNT walls or carbon radicals at an end of the CNT that are not capped during the CNT synthesis process. In some embodiments, these radicals can form a bond with a functionalized substrate. As the radicals can be present at the end of a synthesized CNT, the resulting infused substrate may have the synthesized CNTs bonded at their ends to the substrate surface, creating a comb like pattern on the substrate surface. In some embodiments, the radicals can be present along the walls of the CNTs and can bond to a substrate at these points along the walls. In some embodiments, the synthesized CNTs may be infused to the surface of a substrate based on associative forces that are weaker than covalent bonds. Thus, a variety of bonding motifs are also possible, which can result in a variety of CNT infused substrate structures. The resulting infused substrate can then pass out of reactor 100 for further processing.

The CNT-infused substrates can include a substrate such as a carbon filament, a carbon fiber yarn, a carbon fiber tow, a carbon tape, a carbon fiber-braid, a woven carbon fabric, a non-woven carbon fiber mat, a carbon fiber ply, and other 3D woven structures. Filaments include high aspect ratio fibers having diameters ranging in size from between about 1 micron to about 100 microns. Fiber tows are generally compactly associated bundles of filaments and are usually twisted together to give yarns

One of ordinary skill in the art will recognize that one or more controllers can form a controller system that can be adapted to independently sense, monitor and control system parameters including one or more of substrate feed rate, the carrier gas flow rate and pressure, the catalyst flowrate and pressure, the carbon feedstock flowrate and pressure, the heating element, and the temperature within the CNT growth zone. Such a controller system can be an integrated, automated computerized system controller system that receives parameter data and performs various automated adjustments of control parameters or a manual control arrangement, as is understood by one of ordinary skill in the art.

In some embodiments, a post functionalization process for functionalizing the carbon nanotubes can be performed to promote adhesion of the carbon nanotubes to a resin matrix. Functionalization generally involves the creation of polar functional groups on the surface of the CNT. Suitable functional groups for can include, but are not limited to, amine groups, carbonyl groups, carboxyl groups, fluorine-based groups, silane groups, siloxane groups, and any combination thereof. Suitable techniques can include, but are not limited to, sputtering, plasma functionalization, and passing the substrate through one or more suitable chemical solutions.

While FIG. 1 illustrates a generally vertical reactor design, the reactor system is not limited to the design shown in FIG. 1. In some embodiments, the reactor, including the CNT growth zone, can be oriented in a non-vertical arrangement. As the catalyst particles are atomized, the flow of gases through the CNT growth zone can generally entrain the catalyst particles and any synthesized CNTs along with the bulk gas flow. In some embodiments, the catalyst particles may pass through a CNT growth zone in a generally horizontal direction before passing to a dispersion hood outside the CNT growth zone. Thus, the orientation of the reactor can vary.

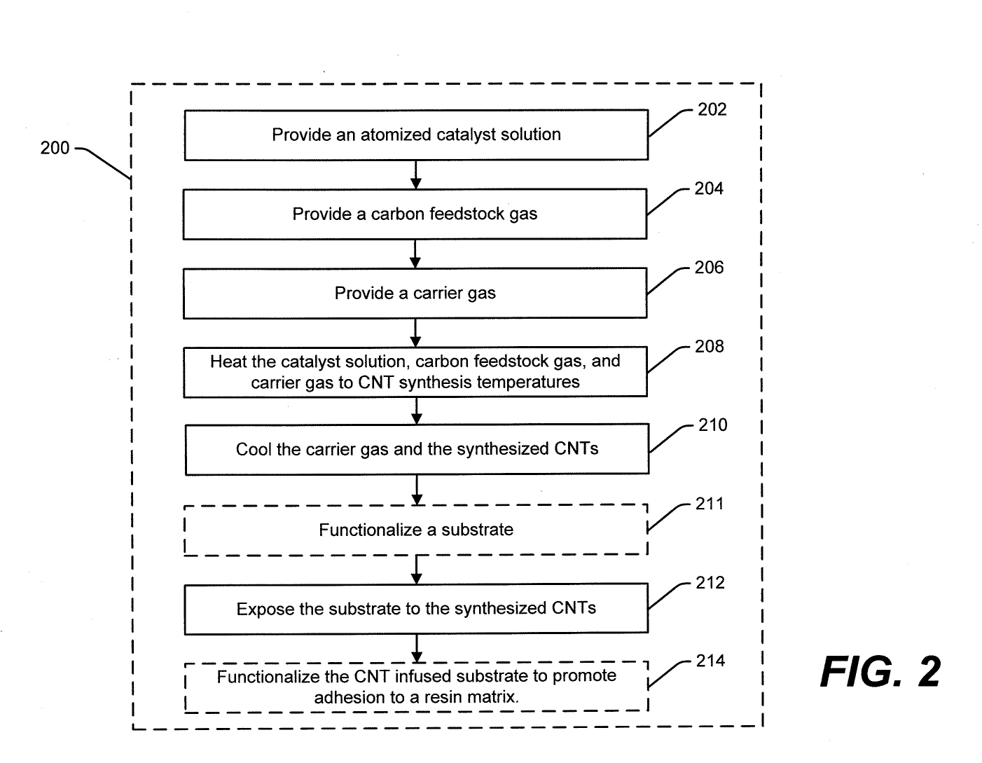

FIG. 2 illustrates a flow chart of a method for synthesizing CNTs. In some embodiments, an atomized catalyst solution is provided in step 202 along with a carbon feedstock gas in step 204 and carrier gas in step 206. In some embodiments, the catalyst solution, the carbon feedstock, and/or the carrier gas are combined prior to atomization and heating of the solution. The catalyst solution, the carbon feedstock gas, and the carrier gas are then heated to CNT synthesis temperatures in step 208. The CNT synthesis temperature can range from about 450° C. to about 1000° C. The mixture is maintained in a CNT growth zone at the CNT synthesis temperatures for an amount of time sufficient to synthesize CNTs of a desired length and size. The synthesized CNTs then pass along with the carrier gas and are cooled in step 210. The mixture may pass through a device such as a dispersion hood to cool to a temperature ranging from about 25° C. to about 450° C. The cooling can avoid the degradation of a temperature sensitive substrate and/or the removal of the sizing that can otherwise compromise the substrate properties. The synthesized CNTs can then be exposed to a substrate.

As shown in FIG. 2, a substrate can be optionally functionalized at step 211 before being exposed to the synthesized CNTs. After being introduced to a CNT growth reactor, the substrate can be exposed to the synthesized CNTs that pass through the cooling zone in step 212. In some embodiments, the substrate can be introduced on a dynamic basis. The synthesized CNTs can bond with the substrate to produce a CNT infused substrate. The CNT infused substrate can then pass out of the reactor for further use or processing. In some embodiments, the CNT infused substrate can be optionally functionalized to improve the adhesion of the CNT infused substrate with a resin matrix.

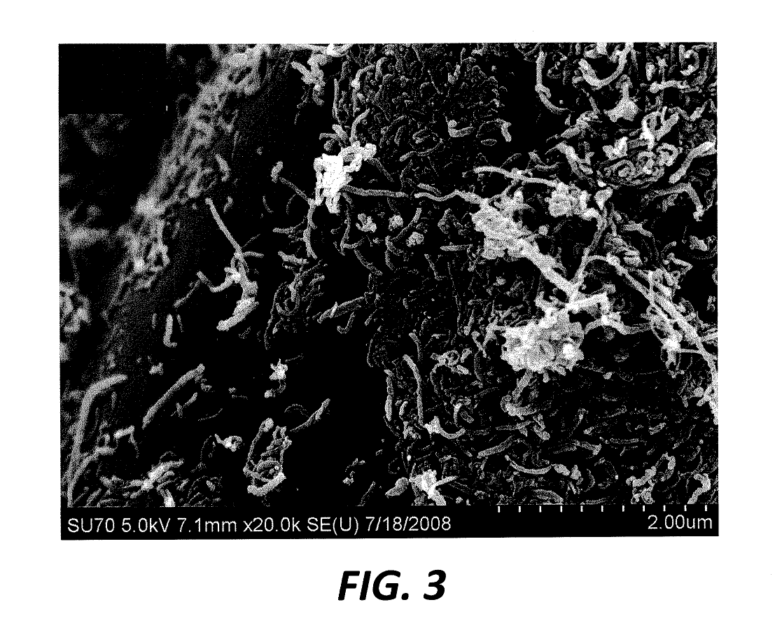

The CNT synthesis processes and systems described herein can provide a CNT-infused substrate with uniformly distributed CNTs on the substrate. For example, FIG. 3 depicts an E-Glass fiber with CNTs infused on its surface via a vertical furnace growth chamber in accordance with some embodiments of the invention. Higher density and shorter CNTs can be useful for improving mechanical properties, while longer CNTs with lower density are useful for improving thermal and electrical properties, although increased density is still favorable. A lower density can result when longer CNTs are grown. This can be the result of the higher temperatures and more rapid growth causing lower catalyst particle yields.

In some embodiments, the CNT infused substrate can be used to form a composite material. Such composite materials can comprise a matrix material to form a composite with the CNT-infused substrate. Matrix materials useful in the present invention can include, but are not limited to, resins (polymers), both thermosetting and thermoplastic, metals, ceramics, and cements. Thermosetting resins useful as matrix materials include phthalic/maelic type polyesters, vinyl esters, epoxies, phenolics, cyanates, bismaleimides, and nadic end-capped polyimides (e.g., PMR-15). Thermoplastic resins include polysulfones, polyamides, polycarbonates, polyphenylene oxides, polysulfides, polyether ether ketones, polyether sulfones, polyamide-imides, polyetherimides, polyimides, polyarylates, and liquid crystalline polyester. Metals useful as matrix materials include alloys of aluminum such as aluminum 6061, 2024, and 713 aluminum braze. Ceramics useful as matrix materials include carbon ceramics, such as lithium aluminosilicate, oxides such as alumina and mullite, nitrides such as silicon nitride, and carbides such as silicon carbide. Cements useful as matrix materials include carbide-base cermets (tungsten carbide, chromium carbide, and titanium carbide), refractory cements (tungsten-thoria and barium-carbonate-nickel), chromium-alumina, nickel-magnesia iron-zirconium carbide. Any of the above-described matrix materials can be used alone or in combination.

### Example 1

This prophetic example shows how a carbon fiber material can be infused with CNTs in a continuous process utilizing an embodiment of the vertical furnace.

FIG. 1 depicts system 100 for producing CNT-infused fiber in accordance with the illustrative embodiment of the present invention. System 100 includes a catalyst source 104, carbon feedstock source 106, and carrier gas source 102, CNT growth zone 112, gas/vapor inlet device 108, a heating element 110, a dispersion hood 114, an infusion chamber 116, a plasma system (not illustrated), and a carbon fiber substrate 118.

Carrier gas source 102 provides a flow of nitrogen gas at a rate of about 60 liters/minute, which mixes with acetylene gas from the carbon feedstock source 106 supplied at a rate of about 1.2 liters/minute. The nitrogen/acetylene gas mixture is used as the atomizing gas in a nebulizer spray system, gas/vapor inlet device 108, where a 1% mass iron acetate solution in isopropyl alcohol is used as the catalyst source 104.

The atomized catalyst/carrier/feedstock gas mixture is introduced to an about 2.5 cm diameter, 92 cm long CNT growth zone 112. CNT growth zone 112 is heated by two independently controlled heating elements 110. The heating elements are stacked one on top of the other, each of a length of about 46 cm long. The first heating element is used to preheat the gas/vapor mixture to CNT growth temperatures. The second heating element is used to maintain growth temperature for the necessary growth residence time for the proper length CNT. In this example, the gas/vapor residence time is about 30 seconds which allows for a uniform CNT length of about 20 microns.

Vapor phase CNTs are gravity assisted to dispersion hood 114 where the size of the zone increases from about 2.5 cm to an about 2.5×7.5 cm rectangular cross section. The dispersion hood spreads out falling vapor phase CNTs for a more uniform application to fibers passing by beneath the hood in CNT infusion chamber 116.

During the production of the vapor phase CNTs, Carbon fiber substrate 118 is exposed to a plasma system where controlled oxygen treatment is used to functionalize the fiber surface. An argon based plasma is used with a mixture of about 1% oxygen by volume to apply carbonyl and carboxyl functional groups on the surface of carbon fiber substrate 118.

Functionalized carbon fiber substrate 118 is pulled through CNT infusion chamber 116 where vapor phase CNTs pass through dispersion hood 114 and applied to the carbon fiber surface. Carbonyl and carboxyl functional groups act as infusion points for CNTs, where dangling carbon bonds at the CNT ends or at disorder on the CNT walls provide the bonding point. Fibers are pulled through the infusion chamber at a linespeed of about 150 cm/minute. By varying the linespeed, the density of CNT infusion can be controlled. At the rate described in this example, a density of between about 2000 to about 4000 CNT/μm² is achieved.

CNT infused carbon fiber passes out of CNT infusion chamber 116 and is wound on a spool for packaging and storage. Additional functionalization steps can occur after the CNT infusion process to enhance future CNT to matrix interfacial properties, but this is beyond the scope of this example.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other processes, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. A method comprising:
exposing a catalyst nanoparticle, a carbon feedstock gas, and a carrier gas to a CNT synthesis temperature;
allowing a CNT to form on the catalyst nanoparticle;
cooling the CNT; and
exposing the cooled CNT to a surface of a substrate to form a CNT infused substrate.

2. The method of claim 1 further comprising functionalizing the substrate prior to exposing the substrate to the CNT.

3. The method of claim 1 further comprising functionalizing the CNT infused substrate.

4. The method of claim 2 wherein the substrate is functionalized by adding a functional group selected from the group consisting of an amine group, a carbonyl group, a carboxyl group, a fluorine-containing group, a silane group, a siloxane group, and any combination thereof.

5. The method of claim 1 wherein the substrate comprises at least one material selected from the group consisting of: a carbon fiber, a graphite fiber, a cellulosic fiber, a glass fiber, a metal fiber, a ceramic fiber, a metallic-ceramic fiber, cellulosic fiber, an aramid fiber, and any combination thereof.

6. The method of claim 1 wherein the CNT synthesis temperature is a temperature in the range of from about 450° C. to about 1000° C.

7. The method of claim 1 wherein the CNT is cooled to a temperature in the range of from about 25° C. to about 450° C.

8. The method of claim 1 further comprising:
providing a catalyst solution comprising a catalyst and a solvent; and
atomizing the catalyst solution and allowing the solvent to evaporate leaving the catalyst nanoparticle.

9. The method of claim 1 wherein the catalyst nanoparticle comprises a d-block transition metal.

10. A system comprising;
a carrier gas source that provides a carrier gas;
a catalyst source that provides a catalyst nanoparticle;
a carbon feedstock source that provides a carbon feedstock;
a substrate source that provides a substrate; and
a CNT growth reactor comprising:
an inlet device that receives the carrier gas, the catalyst nanoparticle, and the carbon feedstock and introduces the carrier gas, the catalyst nanoparticle, and the carbon feedstock into a CNT growth zone;
a heating element that heats the carrier gas, the catalyst nanoparticle, and the carbon feedstock to a CNT synthesis temperature within the CNT growth zone to allow a CNT to synthesize on the catalyst and form a synthesized CNT;
a dispersion hood that receives the synthesized CNT and cools the synthesized CNT; and
a CNT infusion chamber that receives the synthesized CNT and the substrate and exposes the substrate to the cooled synthesized CNT to produce a CNT infused substrate.

11. The system of claim 10 wherein the substrate is functionalized.

12. The system of claim 10 wherein the substrate comprises at least one material selected from the group consisting of: a carbon fiber, a graphite fiber, a cellulosic fiber, a glass fiber, a metal fiber, a ceramic fiber, a metallic-ceramic fiber, cellulosic fiber, an aramid fiber, and any combination thereof.

13. The system of claim 10 wherein the CNT synthesis temperature is a temperature in the range of from about 450° C. to about 1000° C.

14. The system of claim 10 wherein the dispersion hood cools the synthesized CNT to a temperature in the range of from about 25° C. to about 450° C.

15. The system of claim 10 wherein the carbon feedstock comprises at least one compound selected from the group consisting of: acetylene, ethylene, methanol, methane, propane, benzene, natural gas, and any combination thereof.

16. A method comprising:
providing a catalyst nanoparticle, a carbon feedstock gas, and a carrier gas;
heating the catalyst nanoparticle, the carbon feedstock gas, and the carrier gas to a CNT synthesis temperature;
allowing a CNT to form on the catalyst nanoparticle;
cooling the CNT;
providing a substrate;
exposing the substrate to the cooled CNT to form a CNT infused substrate; and
forming a composite material, wherein the composite material comprises the CNT infused substrate.

17. The method of claim 16 wherein the substrate is functionalized.

18. The method of claim 16 further comprising functionalizing the CNT infused substrate prior to forming a composite material.

19. The method of claim 16 wherein the substrate is provided on a dynamic basis.

20. The method of claim 16 wherein the composite material further comprises a matrix material, and wherein the matrix material comprises at least one material selected from the group consisting of: a thermosetting resin, a thermoplastic resin, a metal, a ceramic, a cement, and any combination thereof.
